(19) United States
(12) Patent Application Publication
(10) Pub. No.: US 2009/0091888 A1
(43) Pub. Date: Apr. 9, 2009

(54) EMI SHIELDING AND HEAT DISSIPATING STRUCTURE

(76) Inventors: Chao-Chun Lin, Taipei Hsien (TW); Shih-Hong Chen, Taipei Hsien (TW); Cheng-Hsiung Hsu, Taipei Hsien (TW); Tsung-Ying Chung, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/868,970

(22) Filed: Oct. 9, 2007

(51) Int. Cl. H05K 7/20

(52) U.S. Cl. 361/704

(57) ABSTRACT

The present invention discloses an EMI shielding and heat dissipating structure for dissipating heat generated by a chip inside a portable electronic device. The EMI shielding and heat dissipating structure includes an EMI shielding housing for shielding the chip. A first opening is formed on the EMI shielding housing. The EMI shielding and heat dissipating structure further includes a thermal pad disposed on the chip, and an EMI shielding gasket installed on the EMI shielding housing. A second opening is formed on the EMI shielding gasket and located in a position corresponding to the first opening. The EMI shielding and heat dissipating structure further includes a heat-dissipating component installed on the EMI shielding gasket and connected to the thermal pad for dissipating the heat transmitted from the thermal pad.

### BACKGROUND OF THE INVENTION

1. Field of the Invention

The present invention relates to an EMI shielding and heat dissipating structure, and more particularly, to an EMI shielding and heat dissipating structure for dissipating heat outside a portable electronic device and for providing the EMI shielding simultaneously.

2. Description of the Prior Art

Electronic equipment includes electrical components and circuits mounted on a substrate that can be sensitive to electromagnetic interference (EMI) and radio frequency interference (RFI). Such EMI/RFI interference may originate from internal sources within the electronic equipment or from external EMI/RFI interference sources. Interference can cause degradation or complete loss of important signals, rendering the electronic equipment inefficient or inoperable. Accordingly, the radio frequency (RF) circuits (sometimes referred to as RF modules or transceiver circuits) usually require EMI/RFI shielding in order to function properly. The shielding reduces interference not only from external sources, but also from various functional blocks within the module.

Portable electronic devices in the market always utilize metal shielding cases, foil, or conductive weave to reduce the EMI characteristic. Please refer to FIG. 1 . FIG. 1 is a diagram of an EMI shielding structure 10 in the prior art. A chip 12 is disposed on a circuit board 14. The EMI shielding structure 10 includes an EMI shielding housing 16 for shielding the chip 12. The EMI shielding housing 16 includes an EMI shielding frame 18, and an EMI shielding cover 20 connected with the EMI shielding frame 18 and disposed on the circuit board 14 as a grounding end. The electric field inside the EMI shielding housing 16 is approximately zero, thus the chip 12 is well protected. However heat generated by the chip 12 can not be dissipated outside the EMI shielding housing 16 effectively due to the cover of the EMI shielding housing 16. To solve this problem, U.S Pat. No. 7,262,369 discloses a mechanism for providing board level EMI shielding and dissipating heat from one or more electrical components of a board. However an opening for dissipating heat is not disposed corresponding to a heat generator so that the mechanism is only utilized for electronic devices with the heat-distributive characteristic instead of the heat-centralized characteristic. If the heat dissipating issue can not be solved successfully, it reduces reliability and stability of the portable electronic devices.

### SUMMARY OF INVENTION

It is therefore a primary objective of the claimed invention to provide an EMI shielding and heat dissipating structure for solving the above-mentioned problem.

According to the claimed invention, the present invention discloses an EMI shielding and heat dissipating structure for dissipating heat generated by a chip inside a portable electronic device. The EMI shielding and heat dissipating structure includes an EMI shielding housing for shielding the chip. A first opening is formed on the EMI shielding housing. The EMI shielding and heat dissipating structure further includes a thermal pad disposed on the chip, and an EMI shielding gasket installed on the EMI shielding housing. A second opening is formed on the EMI shielding gasket and located in a position corresponding to the first opening. The EMI shielding and heat dissipating structure further includes a heat-dissipating component installed on the EMI shielding gasket and connected to the thermal pad for dissipating the heat transmitted from the thermal pad.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an EMI shielding structure in the prior art.

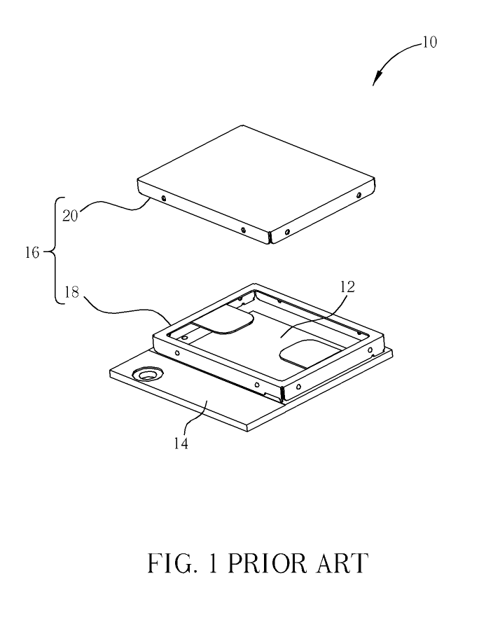

FIG. 2 is an exploded drawing of an EMI shielding and heat dissipating structure of a portable electronic device according to a preferred embodiment of the present invention.

FIG. 3 is a schematic drawing of the EMI shielding and heat dissipating structure of the portable electronic device according to the preferred embodiment of the present invention.

FIG. 4 is a sectional view of the EMI shielding and heat dissipating structure along the line 4-4′ in FIG. 3 according to the preferred embodiment of the present invention.

### DETAILED DESCRIPTION

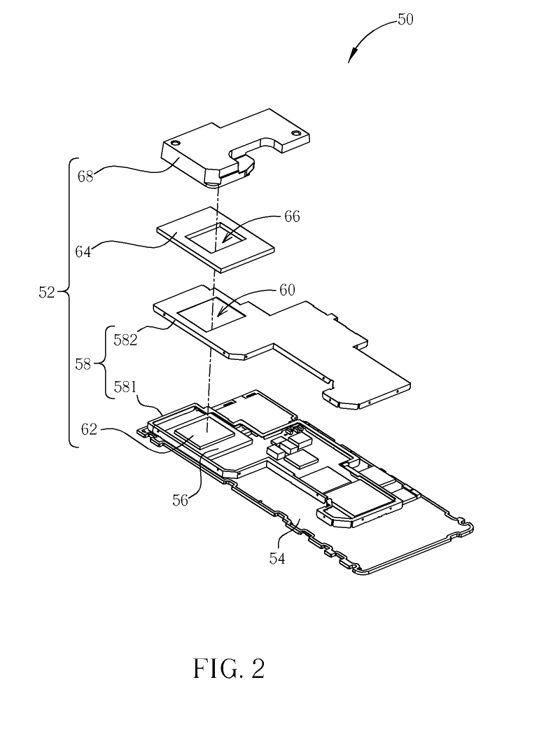

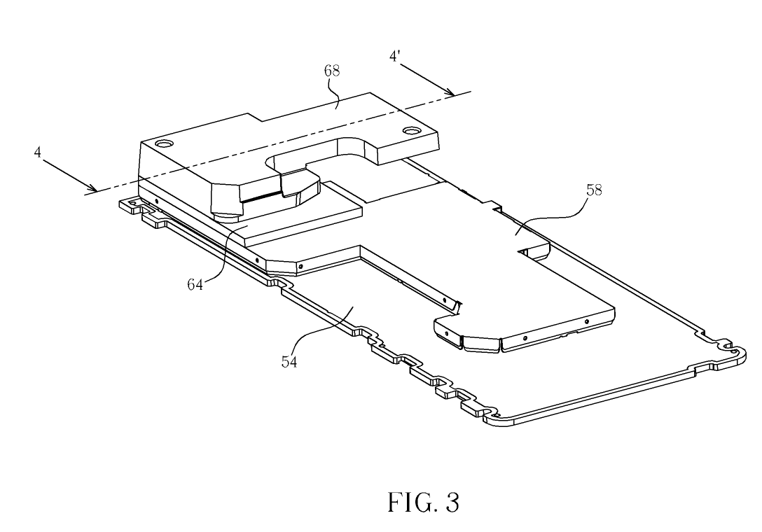

Please refer to FIG. 2 and FIG. 3. FIG. 2 is an exploded drawing of an EMI shielding and heat dissipating structure 52 of a portable electronic device 50 according to a preferred embodiment of the present invention. FIG. 3 is a schematic drawing of the EMI shielding and heat dissipating structure 52 of the portable electronic device 50 according to the preferred embodiment of the present invention. The portable electronic device 50 can be a portable satellite receiver, a personal digital assistance (PDA), a mobile phone, and so on. The portable electronic device 50 includes a circuit board 54, a chip 56 disposed on the circuit board 54, and the EMI shielding and heat dissipating structure 52. The circuit board 54 can be a printed circuit board as a grounding end. The chip 56 can be a processing chip.

The EMI shielding and heat dissipating structure 52 includes an EMI shielding housing 58 for shielding the chip 56. The chip 56 is installed inside the EMI shielding housing 58. A first opening 60 is formed on the EMI shielding housing 58. The EMI shielding housing 58 includes an EMI shielding frame 581 disposed on the circuit board 54, and an EMI shielding cover 582 connected with the EMI shielding frame 581. The first opening 60 is formed on the EMI shielding cover 582. The EMI shielding frame 581 and the EMI shielding cover 582 can be separated or connected in a monolithic structure. The EMI shielding and heat dissipating structure 52 further includes a thermal pad 62 disposed on the chip 56 and located in a position corresponding to the first opening 60 for conducting heat generated by the chip 56. The EMI shielding and heat dissipating structure 52 further includes an EMI shielding gasket 64 installed on the EMI shielding housing 58. The EMI shielding gasket 64 can be made of conductive material, such as a conductive sponge. A second opening 66 is formed on the EMI shielding gasket 64 and located in a position corresponding to the first opening 60. The shapes of the first opening 60, the second opening 66, and the thermal pad 62 can be substantially the same. The EMI shielding and heat dissipating structure 52 further includes a heat-dissipating dissipating component 68 installed on the EMI shielding gasket 64 and connected to the thermal pad 62 for dissipating the heat transmitted from the thermal pad 62. The heat-dissipating component 68 can be a heat sink made of metal material. Since the shapes of the first opening 60, the second opening 66, and the thermal pad 62 are substantially the same, a top surface of the thermal pad 62 is attached to a bottom surface of the heat-dissipating component 68 entirely.

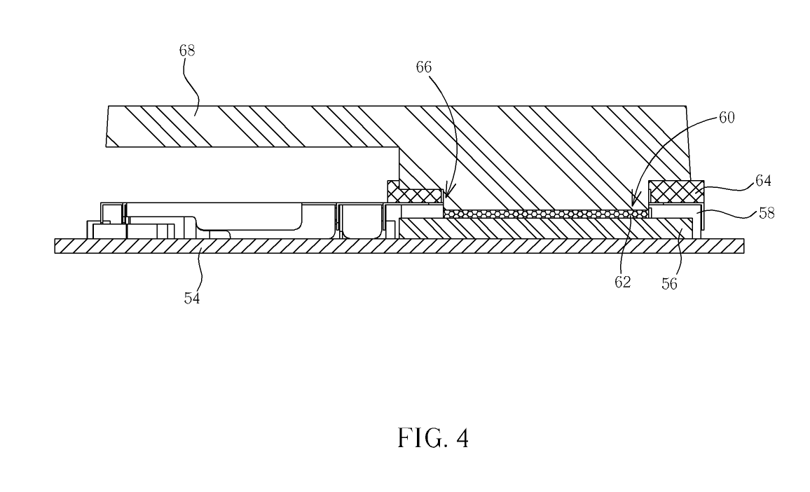

Please refer to FIG. 4. FIG. 4 is a sectional view of the EMI shielding and heat dissipating structure 52 along the line 4-4′ in FIG. 3 according to the preferred embodiment of the present invention. As shown in FIG. 4, the heat-dissipating component 68 is electrically connected to the circuit board 54 via the contact of the heat-dissipating component 68, the EMI shielding gasket 64, the EMI shielding housing 58, and the circuit board 54 so that the heat-dissipating component 68 is coupled to a grounding end. The EMI shielding gasket 64 is capable of conducting electricity between the heat-dissipating component 68 and the EMI shielding housing 58. Besides, the top surface of the thermal pad 62 is attached to the bottom surface of the heat-dissipating component 68 entirely, so the heat generated by the chip 56 is conducted to the heat-dissipating component 68 via the thermal pad 62. And then the heat-dissipating component 68 dissipates the heat transmitted from the thermal pad 62 outside the EMI shielding and heat dissipating structure 52. The EMI shielding gasket 64 is not only capable of conducting electricity between the heat-dissipating component 68 and the EMI shielding housing 58, but also conducting the heat transmitted from the chip 56 via the EMI shielding housing 58 to the heat-dissipating component 68. Therefore, the heat generated by the chip 56 is also conducted to the heat-dissipating component 68 via the contact of the chip 56, the EMI shielding housing 58, the EMI shielding gasket 64, and the heat-dissipating component 68. And then the heat-dissipating component 68 dissipates the heat transmitted from the thermal pad 62 outside the EMI shielding and heat dissipating structure 52.

In contrast to the prior art, the EMI shielding and heat dissipating structure of the present invention can dissipate heat outside the portable electronic device and provide the EMI shielding simultaneously. Therefore, it increases reliability and stability of the portable electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An EMI shielding and heat dissipating structure for dissipating heat generated by a chip inside a portable electronic device, the EMI shielding and heat dissipating structure comprising:
an EMI shielding housing for shielding the chip, a first opening being formed on the EMI shielding housing;
a thermal pad disposed on the chip;
an EMI shielding gasket installed on the EMI shielding housing, a second opening being formed on the EMI shielding gasket and located in a position corresponding to the first opening; and
a heat-dissipating component installed on the EMI shielding gasket and connected to the thermal pad for dissipating the heat transmitted from the thermal pad.

2. The EMI shielding and heat dissipating structure of claim 1 wherein the EMI shielding housing comprises:
an EMI shielding frame; and
an EMI shielding cover connected with the EMI shielding frame, the first opening being formed on the EMI shielding cover.

3. The EMI shielding and heat dissipating structure of claim 1 wherein the EMI shielding gasket is made of conductive material.

4. The EMI shielding and heat dissipating structure of claim 3 wherein the EMI shielding gasket is a conductive sponge.

5. The EMI shielding and heat dissipating structure of claim 1 wherein the heat-dissipating component is a heat sink.

6. The EMI shielding and heat dissipating structure of claim 1 wherein the shapes of the first opening, the second opening, and the thermal pad are substantially the same.
